(19) United States
(12) Patent Application Publication
(10) Pub. No.: US 2016/0064693 A1
(43) Pub. Date: Mar. 3, 2016

(54) METHOD OF FABRICATING LIGHT SCATTERING LAYER, AND ORGANIC LIGHT EMITTING DIODE INCLUDING THE SAME

(71) Applicant: ELECTRONICS AND TELECOMMUNICATIONS RESEARCH INSTITUTE, Daejeon (KR)

(72) Inventors: Jaehyun MOON, Daejeon (KR); Jin Wook SHIN, Daejeon (KR); Jonghee LEE, Daejeon (KR); Seung Koo PARK, Daejeon (KR); JEONG IK LEE, Daejeon (KR); Doo-Hee CHO, Daejeon (KR); Chul Woong JOO, Seoul (KR); Jun-Han HAN, Daejeon (KR)

(73) Assignee: ELECTRONICS AND TELECOMMUNICATIONS RESEARCH INSTITUTE, Daejeon (KR)

(21) Appl. No.: 14/737,231

(22) Filed: Jun. 11, 2015

(30) Foreign Application Priority Data
Aug. 27, 2014 (KR) 10-2014-0112399

(51) Int. Cl. H01L 51/52; H01L 51/50; H01L 51/56; G02B 5/02

(52) U.S. Cl. CPC H01L 51/5268; G02B 5/0268; H01L 51/5064; H01L 51/5092; H01L 51/508; H01L 51/5088; H01L 51/56

(57) ABSTRACT

Provided is a method of fabricating a light scattering layer. The method includes: coating a first surface of a substrate with a nano structure; and etching the substrate exposed to the nano structure by using the nano structure as an etching mask to allow the first surface of the substrate to have a recess to form first partitions protruding from the first surface of the substrate.

### CROSS-REFERENCE TO RELATED APPLICATIONS

This U.S. non-provisional patent application claims priority under 35 U.S.C. §119 of Korean Patent Application No. 10-2014-0112399, filed on Aug. 27, 2014, the entire contents of which are hereby incorporated by reference.

### BACKGROUND OF THE INVENTION

The present invention disclosed herein relates to a method of fabricating a light scattering layer, and an organic light emitting diode including the same.

In recent, demands for product weight reduction, size decrease and inexpensive price are increasing in lighting device and electronic device such as a portable phone or notebook computer. In order to satisfy such demands, an organic light emitting diode (OLED) receives attention as a display device and light emitting device installed in the electronic device and lighting device. In particular, since the OLED has advantages in low power consumption, light weight and inexpensive cost, it is widely used in the electronic device and lighting device.

In recent, researches on increasing light-emitting efficiency of the OLED are being performed. In particular, various researches on showing high light-emitting efficiency even at a lower voltage by externally extracting light emitted from the inside of the OLED are being performed.

### SUMMARY OF THE INVENTION

The present invention provides a method of fabricating a light scattering layer that has simplified processes.

The present invention also provides an organic light emitting diode (OLED) including a light scattering layer.

Tasks to be performed by the present invention are not limited to the above-mentioned tasks and other tasks not mentioned may be clearly understood by a person skilled in the art from the following descriptions.

Embodiments of the present invention provide methods of fabricating a light scattering layer including: coating a first surface of a substrate with a nano structure; and etching the substrate exposed to the nano structure by using the nano structure as an etching mask to allow the first surface of the substrate to have a recess to form first partitions protruding from the first surface of the substrate.

In other embodiments of the present invention, methods of fabricating a light scattering layer, the method includes coating a substrate with a nano structure; applying heat to the substrate to melt the nano structure to form a nano droplet; and etching the substrate exposed to the nano droplet as an etching mask to allow an upper surface of the substrate to have a recess to form protrusions protruding from the upper surface of the substrate.

In still other embodiments of the present invention, organic light emitting diodes (OLED) include a light scattering layer; a first electrode disposed on the light scattering layer; an organic light emitting layer disposed on the first electrode; and a second electrode disposed on the organic light emitting layer, wherein the light scattering layer includes partitions protruding from a surface of the light scattering layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of an organic light emitting diode (OLED) having an internal light scattering layer according to embodiments of the present invention;

FIG. 2A is a perspective view of the light scattering layer in FIG. 1 according to an embodiment of the present invention;

FIG. 2B is a perspective view of the light scattering layer in FIG. 1 according to another embodiment of the present invention;

FIG. 3 is a cross-sectional view of an OLED having an external light scattering layer according to an embodiment of the present invention;

FIG. 4 is a cross-sectional view of an OLED having an internal and external light scattering layer according to an embodiment of the present invention;

FIG. 5A is a perspective view of a first surface of the light scattering layer in FIG. 4;

FIG. 5B is a perspective view of a second surface of the light scattering layer in FIG. 4;

FIGS. 6A to 6D are perspective views of a method of fabricating a light scattering layer and an OLED including the same according to an embodiment of the present invention; and

FIGS. 7A to 7D are perspective views of a method of fabricating a light scattering layer and an OLED including the same according to another embodiment of the present invention.

### DETAILED DESCRIPTION OF PREFERRED EMBODIMENTS

The advantages and features of the present invention, and implementation methods thereof will be clarified through the following embodiments described with reference to the accompanying drawings. The present invention may, however, be embodied in different forms and should not be construed as limited to the embodiments set forth herein. Rather, these embodiments are provided to make this disclosure complete and fully convey the scope of the present invention to a skilled in the art. Further, the present invention is only defined by the scopes of claims. The same reference numerals throughout the disclosure refer to the same components.

The terms used herein are only for explaining embodiments, not limiting the present invention. The terms in a singular form in the disclosure may also include plural forms unless otherwise specified. The terms used herein “comprises” and/or “comprising” do not exclude the presence or addition of one or more additional components, steps, operations and/or elements other than the components, steps, operations and/or elements that are mentioned.

Also, embodiments in the present disclosure are described with reference to ideal, exemplary cross-sectional views and/or plan views of the present invention. The thicknesses of layers and regions in the drawings are exaggerated for the effective description of technical content. Thus, the forms of exemplary views may vary depending on manufacturing technologies and/or tolerances. Thus, embodiments of the present invention are not limited to shown specific forms and also include variations in form produced according to manufacturing processes. For example, an etch region shown as a rectangular shape may have a round shape or a shape having a certain curvature. Thus, regions illustrated in the drawings are exemplary, and the shapes of the regions illustrated in the drawings are intended to illustrate the specific shapes of the regions of elements and not to limit the scope of the present invention.

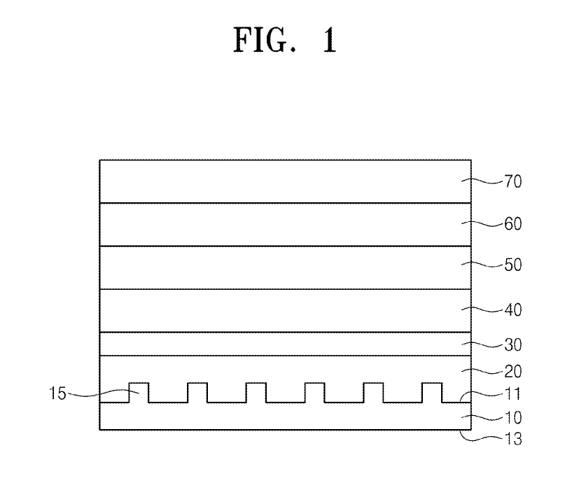

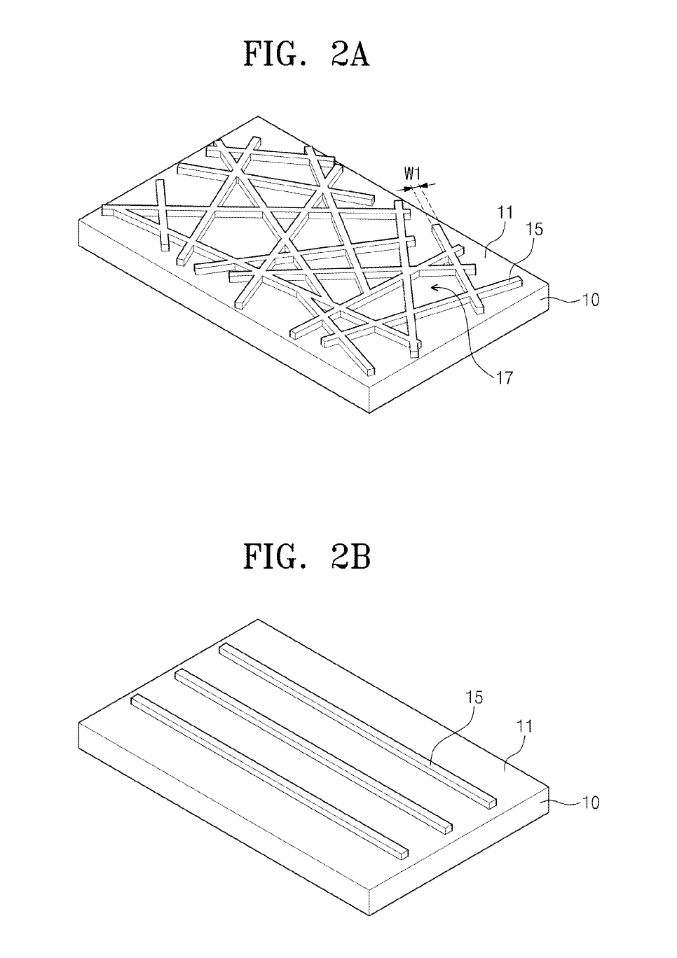

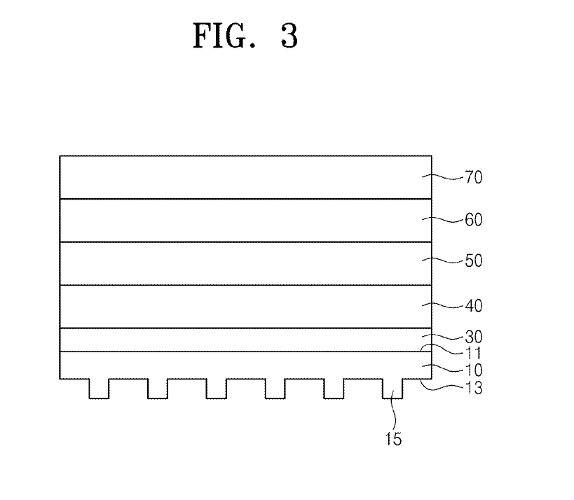

FIG. 1 is a cross-sectional view of an organic light emitting diode (OLED) having an internal light scattering layer according to embodiments of the present invention. FIG. 2A is a schematic perspective view of a light scattering layer according to an embodiment of the present invention. FIG. 2B is a perspective view of the light scattering layer in FIG. 1 according to another embodiment of the present invention.

Referring to FIG. 1, the OLED includes a light scattering layer 10, a planarization layer 20, a first electrode 30, a hole transfer layer 40, an organic light emitting layer 50, an electron transfer layer 60 and a second electrode 70.

The light scattering layer 10 includes a first surface 11 and a second surface 13 opposite to the first surface 11. The planarization layer 20 is disposed on the first surface 11 of the light scattering layer 10. The light scattering layer 10 may be formed of a transparent material (e.g., glass or polymeric material).

Referring further to FIG. 2A, the light scattering layer 10 may include a plurality of partitions 15 protruding from the first surface 11 of the light scattering layer 10. The partitions 15 may be randomly disposed. Since adjacent partitions 15 cross each other, the light scattering layer 10 may have a space 17 formed by different partitions 15. The bottom portion of the space 17 may be configured by the first surface 11 of the light scattering layer 10 and the sidewalls of the space 17 may be configured by different partitions 15.

According to another embodiment of the present invention, referring to FIG. 2B, the partitions 15 may be aligned in fashion of stripes. The widths W1 of the partitions 15 may be about 100 nm to about 2000 nm. The widths W1 of the partitions 15 may be the same or different from one another. Since the light confined in the interface between the light scattering layer 10 and the first electrode 30 impinges into the partitions 15, is scattered and enters the organic light emitting layer 50, the light scattering layer 10 may have a function of enhancing light extraction. Thus, the light scattering layer 10 may enhance the internal light extraction of the OLED.

Referring back to FIG. 1, the planarization layer 20 may be configured to cover the light scattering layer 10 and fill the space 17 in direct contact with the upper surface of the light scattering layer 10. The planarization layer 20 may cover the first surface 11 of the light scattering layer 10 to provide a planar surface. The planarization layer 20 may contact with the first surface 11 of the light scattering layer 10. The planarization layer 20 may have a high refractive index, for example n>about 1.5. The planarization layer 20 may include at least one of an inorganic substance, organic, organic-inorganic hybrid material, polymer and combination thereof. The inorganic substance may include at least one of e.g., TiO₂, TiO₂—SiO₂, ZrO₂, ZnS, SnO₂, and In₂O₃. The polymer may include at least one of e.g., a polyvinyl phenol resin, epoxy resin, polyimide resin, polystyrene resin, polycarbonate resin, polyethylene resin, PMMA resin, polypropylene resin and silicon resin.

The first electrode 30 is disposed on the planarization layer 20. The first electrode 30 may be an anode electrode. The first electrode 30 may include a material having a lower refractive index than the planarization layer 20. In other words, a refractive index of the planarization layer 20 is higher than a refractive index of the first electrode 30. The first electrode 30 may include a conductive material having transparency. The first electrode 30 may be a Transparent Conductive Oxide (TCO), such as an Indium Tin Oxide (ITO), Indium Zinc Oxide (IZO), carbon based electrode, conductive polymeric material or conductive nano wire.

The hole transfer layer 40 is disposed on the first electrode 30. Specifically, the hole transfer layer 40 may include a hole injection layer (not shown) and a hole transport layer (not shown) that are sequentially stacked on the first electrode 30.

A Highest Occupied Molecular Orbital (HOMO) represents the highest energy level of a valence band and a Lowest Unoccupied Molecular Orbital (LUMO) represents the lowest energy level of a conduction band.

By decreasing the difference between the work function level of the first electrode 30 and the HOMO level of the hole transport layer, the hole injection layer performs a function of facilitating the injection of a hole into the hole transport layer.

The hole transport layer may provide the organic light emitting layer 50 with a hole moving through the hole injection layer. The HOMO level of the hole transport layer may be higher than the HOMO level of the organic light emitting layer 50.

The organic light emitting layer 50 is disposed on the hole transfer layer 40. It may include a fluorescent material or phosphor. The organic light emitting layer 50 may include DPVBi, IDE 120, IDE 105, Alq3, CBP, DCJTB, BSN, DPP, DSB, PESB, PPV derivatives, PFO derivatives, C545t, Ir(ppy)3, or PtOEP, for example. The organic emission layer 50 may be a single layer or multiple layers.

The electron transfer layer 60 is disposed on the organic light emitting layer 50. Specifically, the electron transfer layer 60 includes an electron transport layer (not shown) and an electron injection layer (not shown) that are sequentially stacked on the organic light emitting layer 50.

The electron injection layer may include a material having high electron mobility. The electron injection layer may include lithium (Li), magnesium (Mg), aluminum (Al), calcium (Ca), silver (Ag) or cesium (Cs). The electron injection layer may include lithium fluoride (LiF) or cesium fluoride (CsF). The electron injection layer performs a function of stably supplying an electron to the organic light emitting layer 50.

The second electrode 70 is disposed on the electron transfer layer 60. The second electrode 70 may be a negative electrode. The second electrode 70 may include a conductive material having a lower work function level than the first electrode 30. The second electrode 70 may include a conductive material being semi-transparent or having high reflectance. The second electrode 70 may include aluminum (Al), gold (Au), silver (Ag), iridium (Ir), molybdenum (Mo), palladium (Pd) or platinum (Pt), for example.

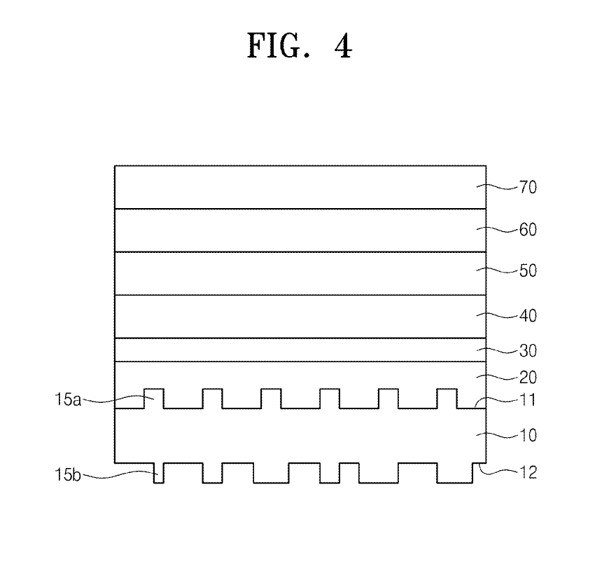

FIG. 3 is a cross-sectional view of an OLED having an external light scattering layer according to an embodiment of the present invention. For the simplicity of description, the same reference numerals as those in FIG. 1 are used for substantially the same components as those in FIG. 1 and the descriptions of corresponding components are omitted, in the embodiment in FIG. 3.

Referring to FIG. 3, the OLED includes a light scattering layer 10, a first electrode 30, a hole transfer layer 40, an organic light emitting layer 50, an electron transfer layer 60 and a second electrode 70.

The first electrode 30 is disposed on the light scattering layer 10. The light scattering layer 10 includes a first surface 11 and a second surface 13 opposite to the first surface 11. The first surface 11 of the light scattering layer 10 is a planar surface and may be in direct contact with the first electrode 30.

The second surface 13 the light scattering layer 10 may include a plurality of partitions 15 protruding from the second surface 13. The partitions 15 may be randomly disposed. Since adjacent partitions 15 cross each other, the light scattering layer 10 may have a space 17 (see FIG. 2A) formed by different partitions 15. The bottom portion of the space 17 may be configured by the second surface 13 of the light scattering layer 10 and the sidewalls of the space 17 may be configured by different partitions 15. The widths W1 of the partitions 15 may be about 100 nm to about 2000 nm. The widths W1 of the partitions 15 may be the same or different from one another.

Since light not entering the interface between the air and the light scattering layer 10 impinges into the partitions 15, is scattered and enters the organic light emitting layer 50, the light scattering layer 10 may have a function of enhancing light extraction. Thus, the light scattering layer 10 may enhance the external light extraction of the OLED.

The hole transfer layer 40, organic light emitting layer 50, electron transfer layer 60 and second electrode 70 may be sequentially disposed on the first electrode 30.

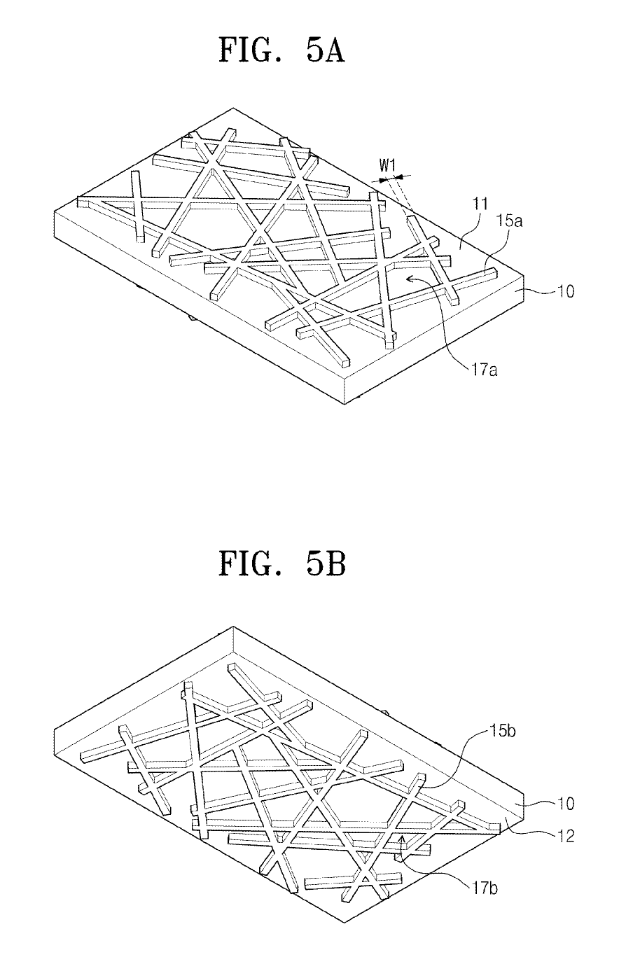

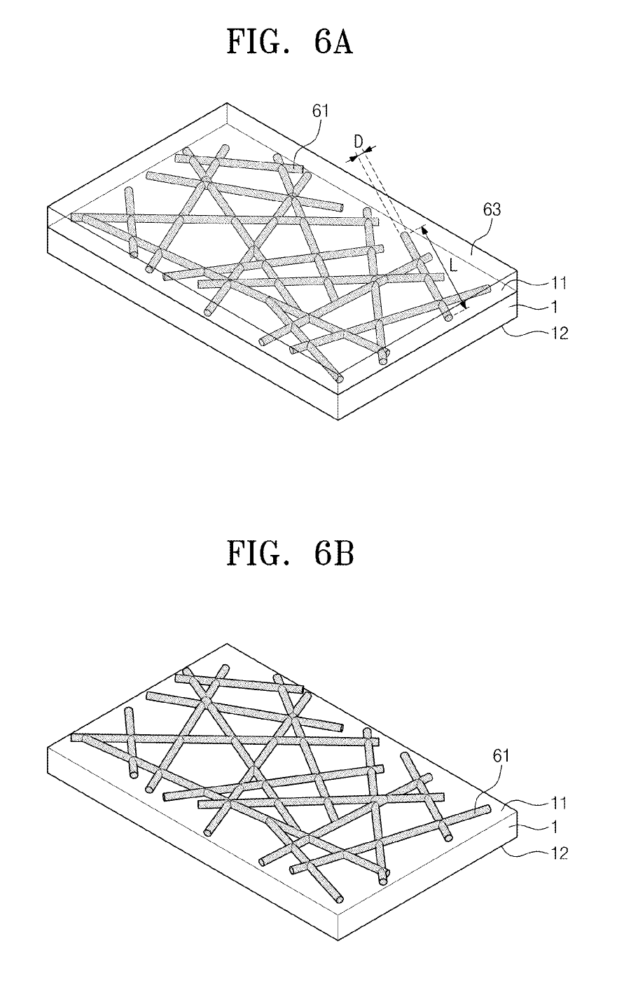

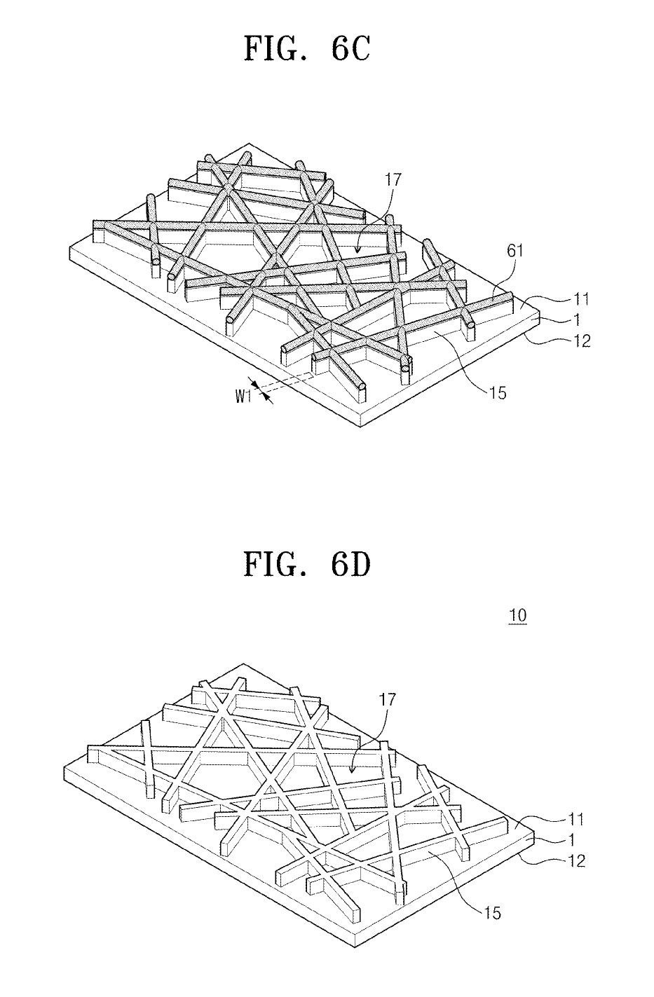

FIG. 4 is a cross-sectional view of an OLED having an internal and external light scattering layer according to an embodiment of the present invention. FIG. 5A is a perspective view of a first surface of the light scattering layer in FIG. 4. FIG. 5B is a perspective view of a second surface of the light scattering layer in FIG. 4. For the simplicity of description, the same reference numerals as those in FIG. 1 are used for substantially the same components as those in FIG. 1 and the descriptions of corresponding components are omitted, in the embodiment in FIG. 4.

Referring to FIGS. 4, 5A and 5B, the OLED includes a light scattering layer 10, a planarization layer 20, a first electrode 30, a hole transfer layer 40, an organic light emitting layer 50, an electron transfer layer 60 and a second electrode 70.

The light scattering layer 10 includes a first surface 11 and a second surface 13 opposite to the first surface 11. The planarization layer 20, first electrode 30, hole transfer layer 40, organic light emitting layer 50, electron transfer layer 60 and second electrode 70 are sequentially stacked on the first surface 11 of the light scattering layer 10. The light scattering layer 10 may include a plurality of upper partitions 15a protruding from the first surface 11 of the light scattering layer 10. The upper partitions 15a may be randomly disposed. Since adjacent partitions 15 cross each other, the light scattering layer 10 may have a first space 17a formed by different upper partitions 15a. The bottom portion of the first space 17a may be configured by the first surface 11 of the light scattering layer 10 and the sidewalls of the first space 17a may be configured by different upper partitions 15a. The widths W1 of the upper partitions 15a may be about 100 nm to about 2000 nm. The widths W1 of the upper partitions 15a may be the same or different from one another.

The planarization layer 20 may be disposed on the first surface 11 of the light scattering layer 10. The planarization layer 20 may be configured to cover the light scattering layer 10 and fill the first space 17a in direct contact with the first surface 11 of the light scattering layer 10. The planarization layer 20 may cover the first surface 11 of the light scattering layer 10 to provide a planar surface.

The light scattering layer 10 may include a plurality of lower partitions 15b protruding from the second surface 13 of the light scattering layer 10. The lower partitions 15b may be randomly disposed. Since adjacent lower partitions 15b cross each other, the light scattering layer 10 may have a second space 17b formed by different lower partitions 15b. The bottom portion of the second space 17b may be configured by the second surface 13 of the light scattering layer 10 and the sidewalls of the second space 17b may be configured by different lower partitions 15b. The widths W2 of the lower partitions 15b may be about 100 nm to about 2000 nm. The widths W2 of the lower partitions 15b may be the same or different from one another. The widths W2 of the lower partitions 15b may be the same as or different from the widths W1 of the upper partitions 15a. The upper partitions 15a of the light scattering layer 10 may scatter light confined in the interface between the light scattering layer 10 and the first electrode 30 to allow light to enter the organic light emitting layer 50, and the lower partitions 15b of the light scattering layer 10 may scatter light not entering the interface between the light scattering layer 10 and the air to allow light to enter the organic light emitting layer 50.

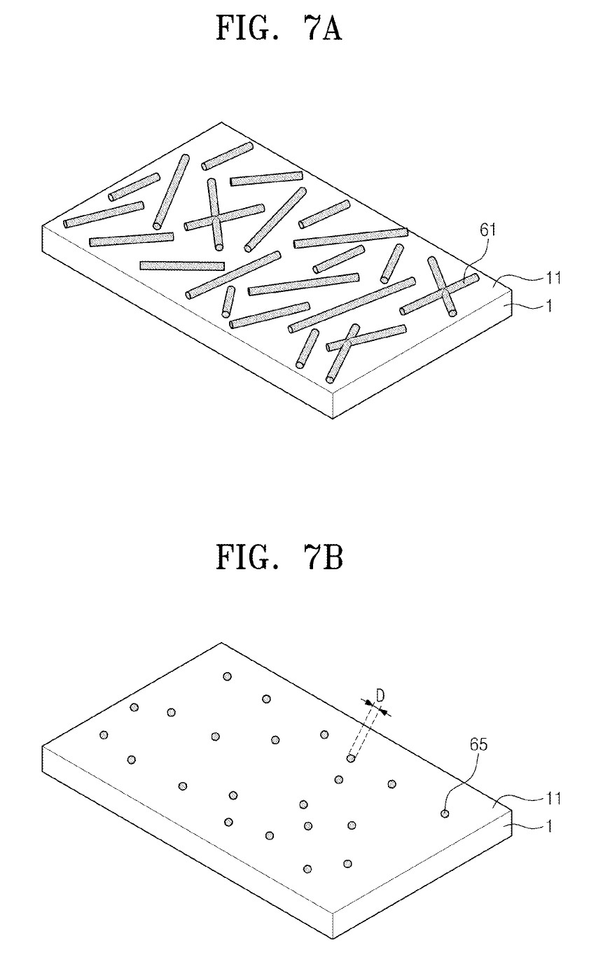

FIGS. 6A to 6D are perspective views of a method of fabricating a light scattering layer and an OLED including the same according to an embodiment of the present invention.

Referring to FIG. 6A, a substrate 1 is provided. The substrate 1 includes a first surface 11 and a second surface 12 opposite to the first surface 11. The substrate 1 may be an organic or polymeric substrate, for example.

The first surface 11 of the substrate 1 is coated with a nano structure 61. The nano structure 61 may be a nano wire or nano fiber. As an example, when the nano structure 61 is the nano wire, the substrate 1 may be coated with a solution 63 to which the nano wire is sprayed. The nano wire may be mixed with the solution 63 and disposed on the first surface 11 of the substrate 1 when the substrate 1 is coated with the solution 63. The substrate 1 may be coated with the solution 63 by using any one of spray coating and slot die coating methods. The solution 63 may be used as the spray solution of the nano structure 61. As other example, when the nano structure 61 is the nano fiber, the substrate 1 may be coated directly with the nano fiber by using electrospinning As another example, the nano structure 61 may be deposited on the substrate 1 by using Langmuir-Blodgett, Electrospinning or contact printing. In this case, a plurality of nano structures 61 may be aligned in a fashion of stripes.

The nano structure 61 may have a diameter D of about 100 nm to about 2000 nm and a length L of about 300 nm to about 3000 nm but is not limited thereto. A plurality of nano structures 61 may have different diameters on the substrate 1. The nano structure 61 may include a metallic material or an inorganic material. The metallic material may include silver (Ag) or gold (Au), for example.

Referring to FIG. 6B, the first surface 11 of the substrate 1 is coated with the solution 63 including the nano structure 61 and then a heat treatment process is performed. The heat treatment process may be performed for the removal of the solution 63. The heat treatment process may be performed by using a typical oven. Heat treatment may also be performed at a temperature of 25° C. to 150° C.

Referring to FIG. 6C, the substrate 1 exposed to the nano structure 61 is etched after the heat treatment process. Specifically, the substrate 1 exposed to the nano structure 61 is etched by using the nano structure 61 as an etching mask to allow the first surface 11 of the substrate 1 to have a recess. The substrate 1 may be etched by using a dry etching (e.g., plasma etching) process.

The first surface 11 of the substrate 1 has the recess, so it is possible to form partitions 15 protruding from the first surface 11 of the substrate 1. The partitions 15 may be a portion of the substrate 1 not etched by the nano structure 61. The partitions 15 may have the same width W1 as the diameter D of the nano structure 61. Thus, the widths W1 of the partitions 15 may be the same or different from one another. The partitions 15 may be formed to be randomly disposed on the substrate 1. Adjacent partitions 15 on the first surface 11 of the substrate 1 cross one another so that the space 17 may be formed. Thus, the bottom portion of the space 17 may be configured by the first surface 11 of the substrate 1 and the sidewalls of the space 17 may be configured by different partitions 15.

Referring to FIG. 6D, the upper surfaces of the partitions 15 are exposed by the removal of the nano structure 61. Specifically, it is possible to remove the nano structure 61 by using a wet etching process, i.e., immersing in an etching solution the substrate 1 on which the nano structure 61 is disposed. The etching solution may be a typical etchant. The substrate 1 may be used as the light scattering layer 10 of the OLED.

According to another embodiment, the substrate 1 may be etched by using the plurality of the nano structures 61 aligned in a fashion of stripes as an etching mask. Thus, the light scattering layer 10 having the partitions 15 aligned a fashion of stripes may be formed as shown in FIG. 2B.

Referring back to FIG. 2A, the planarization layer 20, first electrode 30, hole transfer layer 40, organic light emitting layer 50, electron transfer layer 60 and second electrode 70 are sequentially formed on the light scattering layer 10. The planarization layer 20 may be formed to fill the space 17 of the light scattering layer 10, cover the first surface 11 of the light scattering layer 10, and provide a planar surface.

Referring to FIG. 3, the light scattering layer 10 may include the first surface 11 and the second surface 13 opposite to the first surface 11 and the partitions 15 may be formed to protrude from the second surface 13 of the light scattering layer 10. The first electrode 30, hole transfer layer 40, organic light emitting layer 50, electron transfer layer 60 and second electrode 70 may be sequentially on the first surface 11 of the light scattering layer 10. The first surface 11 of the light scattering layer 10 may be formed to have a planar surface and to be in direct contact with the first electrode 30.

Referring to FIG. 4, it is possible to form the upper partitions 15a on the first surface 11 of the light scattering layer 10 and it is possible to form the lower partitions 15b on the second surface 13 of the light scattering layer 10. Specifically, the upper partitions 15a may be formed by forming the nano structure 61 on the first surface 11 of the substrate 1 and allowing the first surface 11 of the substrate 1 to have a recess by using the nano structure 61 as an etching mask, as described in FIGS. 6A to 6D. After the formation of the upper partitions 15a, the lower partitions 15b may be formed by forming the nano structure 61 on the first second 12 of the substrate 1 and allowing the second surface 12 of the substrate 1 to have a recess by using the nano structure 61 as an etching mask, in the same manner as that of forming the upper partitions 15a.

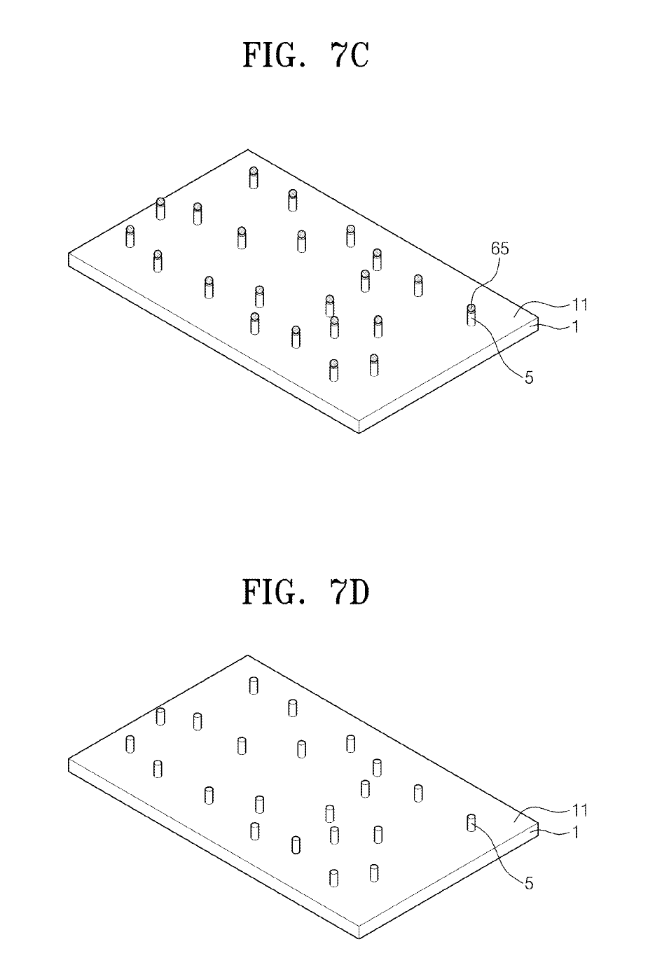

FIGS. 7A to 7D are perspective views of a method of fabricating a light scattering layer according to another embodiment of the present invention. For the simplicity of description, the same reference numerals as those in the embodiment above are used for substantially the same components as those in the embodiment above and the descriptions of corresponding components are omitted, in the other embodiment in FIGS. 7A to 7D.

Referring to FIG. 7A, the first surface 11 of the substrate 1 is coated with the nano structure 61. The nano structure 61 may be a nano wire or nano fiber.

Referring to FIG. 7B, the substrate 1 coated with the nano structure 61 is heated, so the nano structure 61 melts to form a nano droplet 65. The melting temperature of the nano structure 61 may be lower than the melting point of a material included in a typical nano structure 61. The nano droplet 65 may include a metallic material such as silver (Ag) or gold (Au), for example. The nano droplet 65 may have a diameter D of about 100 nm to about 2000 nm.

Referring to FIG. 7C, the substrate 1 exposed to the nano droplet 65 is etched. Specifically, the substrate 1 exposed to the nano droplet 65 is etched by using the nano droplet 65 as an etching mask to allow the first surface 11 of the substrate 1 to have a recess. Thus, it is possible to form protrusions 5 protruding from the first surface 11 of the substrate 1. The protrusions 5 may be a portion of the substrate 1 not etched by the nano droplet 65. The protrusions 5 may have different widths and sizes depending on the size and/or diameter of the nano droplet 65. Each of the protrusions 5 may not cross one another and may be formed at intervals on the first surface 11 of the substrate 1. The substrate 1 may be etched by using a dry etching (e.g., plasma etching) process.

Referring to FIG. 7D, the nano droplet 65 is removed. Specifically, it is possible to remove the nano droplet 65 by using a wet etching process, i.e., immersing, the substrate 1 coated with the nano droplet 65, in the etching solution. The substrate 1 may be used as the light scattering layer of the OLED.

According to an embodiment of the present invention, the nano structure is used as the etching mask to form the light scattering layer. Since the nano structures are randomly disposed without a planned orientation and used as the etching mask, it is possible to form randomly disposed patterns. Thus, it is possible to form a light scattering layer capable of being applied to light having various wavelengths and the fabricating process of the light scattering layer may be simplified.

While embodiments of the present invention are described with reference to the accompanying drawings, a person skilled in the art may understand that the present invention may be practiced in other particular forms without changing technical spirits or essential characteristics. Therefore, embodiments described above should be understood as illustrative and not limitative in every aspect.

What is claimed is:

1. A method of fabricating a light scattering layer, the method comprising:
coating a first surface of a substrate with a nano structure; and
etching the substrate exposed to the nano structure by using the nano structure as an etching mask to allow the first surface of the substrate to have a recess to form first partitions protruding from the first surface of the substrate.

2. The method of claim 1, wherein the first partitions are randomly disposed to cross one another.

3. The method of claim 2, wherein a space is formed by different partitions crossing one another on the first surface of the substrate, wherein a bottom portion of the space is configured by the first surface of the substrate and sidewalls of the space are configured by different partitions.

4. The method of claim 1, wherein the coating of the first surface of the substrate with the nano structure comprises:
coating the first surface of the substrate with a solution to which the nano structure is sprayed; and
removing the solution.

5. The method of claim 1, wherein the substrate includes a second surface opposite to the first surface, wherein the method further comprises, after the forming of the first partitions:
disposing the nano structure on the second surface of the substrate; and
etching the substrate exposed to the nano structure by using the nano structure as the etching mask to allow the second surface of the substrate to have a recess to form second partitions protruding from the second surface of the substrate.

6. The method of claim 1, further comprising removing the nano structure after the forming of the first partitions.

7. The method of claim 1, wherein the nano structure is a nano wire or nano fiber.

8. The method of claim 1, wherein the nano structure comprises a metallic material or an inorganic material.

9. The method of claim 1, wherein the first partitions are formed to be aligned in stripes.

10. A method of fabricating a light scattering layer, the method comprising:
coating a substrate with a nano structure;
applying heat to the substrate to melt the nano structure to form a nano droplet; and
etching the substrate exposed to the nano droplet as an etching mask to allow an upper surface of the substrate to have a recess to form protrusions protruding from the upper surface of the substrate.

11. An organic light emitting diode (OLED) comprising:
a light scattering layer;
a first electrode disposed on the light scattering layer;
an organic light emitting layer disposed on the first electrode; and
a second electrode disposed on the organic light emitting layer,
wherein the light scattering layer comprises partitions protruding from one surface of the light scattering layer.

12. The organic light emitting diode (OLED) of claim 11, wherein the partitions are randomly disposed and cross one another.

13. The organic light emitting diode (OLED) of claim 12, wherein the light scattering layer comprises a space formed by adjacent partitions crossing one another,
wherein a bottom portion of the space is configured by the one surface of the light scattering layer and sidewalls of the space are configured by different partitions.

14. The organic light emitting diode (OLED) of claim 11, wherein each of the partition has a width of about 100 nm to about 2000 nm.

15. The organic light emitting diode (OLED) of claim 11, wherein the light scattering layer comprises other surface opposite to the one surface of the light scattering layer,
wherein the light scattering layer further comprises partitions protruding from the other surface of the light scattering layer.

16. The organic light emitting diode (OLED) of claim 11, further comprising a planarization layer disposed between the light scattering layer and the first electrode,
wherein the one surface of the light scattering layer contacts with the planarization layer.

17. The organic light emitting diode (OLED) of claim 11, wherein the light scattering layer comprises other surface opposite to the one surface of the light scattering layer,
wherein the other surface of the light scattering layer contacts with the first electrode.

18. The organic light emitting diode (OLED) of claim 11, wherein the partitions are aligned in stripes.

19. The organic light emitting diode (OLED) of claim 11, further comprises:
a hole transfer layer disposed between the first electrode and the organic emitting layer; and
an electron transfer layer disposed between the organic emitting layer and the second electrode.
